(19) United States
(12) Patent Application Publication
(10) Pub. No.: US 2024/0427229 A1
(43) Pub. Date: Dec. 26, 2024

(54) MANUFACTURING METHOD FOR PHOTOMASK, AND PHOTOMASK

(71) Applicant: Kioxia Corporation, Tokyo (JP)

(72) Inventors: Katsuyoshi KODERA, Yokohama Kanagawa (JP); Yukio OPPATA, Chiba Chiba (JP); Shoji MIMOTOGI, Yokohama Kanagawa (JP)

(21) Appl. No.: 18/734,773

(22) Filed: Jun. 5, 2024

(30) Foreign Application Priority Data
Jun. 20, 2023 (JP) 2023-100953

(51) Int. Cl. G03F 1/32; G03F 1/36; G03F 1/60; G03F 1/70

(52) U.S. Cl. CPC G03F 1/32; G03F 1/36; G03F 1/60; G03F 1/70

(57) ABSTRACT

A method of manufacturing a photomask comprises forming a mask film on a surface of a substrate, and forming, with the mask film, a first mask pattern in a first region of the substrate and a second mask pattern in a second region of the substrate. A coverage ratio of the first mask pattern is different from a coverage ratio of the second mask pattern. A light transmittance rate of light through the substrate in the first region and the first mask pattern is different from a light transmittance rate of the light through the substrate in the second region and the second mask pattern.

### CROSS-REFERENCE TO RELATED APPLICATION

This application is based upon and claims the benefit of priority from Japanese Patent Application No. 2023-100953, filed Jun. 20, 2023, the entire contents of which are incorporated herein by reference.

### FIELD

Embodiments described herein relate generally to a manufacturing method for a photomask, and a photomask.

### BACKGROUND

In a process of exposing a resist film using a photomask, it is desirable that a process margin is large. Achieving this is difficult because an optimal light transmittance rate for the photomask varies according to the pattern of the photomask.

### BRIEF DESCRIPTION OF THE DRAWINGS

FIG. 1 illustrates a cross-sectional view of a photomask according to a first embodiment.

FIG. 2 is a graph showing characteristics of photomasks of different types.

FIG. 3 is a graph showing characteristics of a halftone mask.

FIGS. 4A and 4B illustrate plan views of an example of photomask patterns according to the first embodiment.

FIGS. 5A and 5B illustrate plan views of another example of photomask patterns according to the first embodiment.

FIGS. 6 and 7 are graphs showing a relationship between a duty ratio and a normalized image log-slope (NILS) value of a halftone photomask according to the first embodiment.

FIGS. 8A to 8E are graphs showing latent image intensity distributions corresponding to different duty ratios of a photomask.

FIGS. 9A and 9B are graphs showing characteristics of a halftone photomask.

FIG. 10 illustrates a cross-sectional view of a photomask according to a second embodiment.

FIG. 11 illustrates a cross-sectional view of a photomask according to a third embodiment.

FIGS. 12A to 12D are graphs showing characteristics of photomasks to design the photomask according to the third embodiment.

FIG. 13 is a flowchart showing a design method of a pattern of a photomask according to a comparative example of a fourth embodiment.

FIG. 14 is a flowchart showing a design method of a pattern of a photomask according to the fourth embodiment.

FIGS. 15A and 15B are cross-sectional diagrams showing a manufacturing method of a photomask according to a fifth embodiment.

FIGS. 16A to 16C are cross-sectional diagrams showing a manufacturing method of a photomask according to a sixth embodiment.

FIGS. 17A to 17C are cross-sectional diagrams showing a manufacturing method of a photomask according to a seventh embodiment.

### DETAILED DESCRIPTION

Embodiments provide a manufacturing method of a photomask, and a photomask, which are capable of improving a process margin.

In general, according to an embodiment, a method of manufacturing a photomask comprises forming a mask film on a surface of a substrate, and forming, with the mask film, a first mask pattern in a first region of the substrate and a second mask pattern in a second region of the substrate. A coverage ratio of the first mask pattern is different from a coverage ratio of the second mask pattern. A light transmittance rate of light through the substrate in the first region and the first mask pattern is different from a light transmittance rate of the light through the substrate in the second region and the second mask pattern.

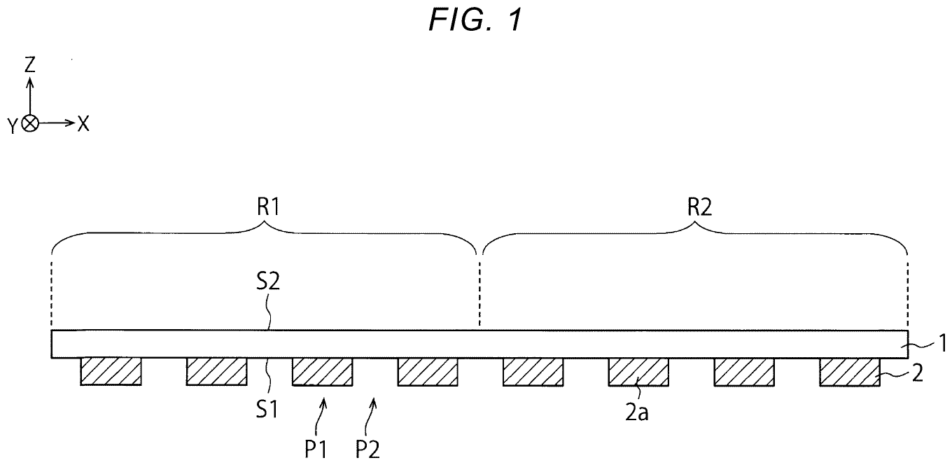

Hereinafter, embodiments of the present disclosure will be described with reference to the drawings. In FIGS. 1 to 17C, the same components are denoted by the same reference symbols, and redundant description will be omitted.

### First Embodiment

FIG. 1 illustrates a cross-sectional view of a photomask according to a first embodiment. The photomask according to the first embodiment is a halftone mask, which is a type of a phase shift mask.

The photomask according to the present embodiment includes a substrate 1 and a halftone film 2. The halftone film 2 includes a halftone film pattern 2a forming a photomask pattern. In the following description, the halftone film 2 is also referred to as “HT film 2”, and the halftone film pattern 2a is also referred to as “HT film pattern 2a”. The halftone film 2 is an example of a mask film.

The substrate 1 is, for example, a transparent substrate such as a glass substrate or a quartz substrate. FIG. 1 shows one surface S1 of the substrate 1 and the other surface S2 of the substrate 1. FIG. 1 further shows X direction and Y direction that are parallel to the surfaces S1 and S2 of the substrate 1 and perpendicular to each other, and Z direction that is perpendicular to the surfaces S1 and S2 of the substrate 1. X direction, Y direction, and Z direction intersect with each other. In the present specification, +Z direction is regarded as an upward direction, and −Z direction is regarded as a downward direction. −Z direction may or may not coincide with a gravity direction. In FIG. 1, the surface S1 is a lower surface of the substrate 1, and the surface S2 is an upper surface of the substrate 1.

The HT film 2 is formed on the surface S1 of the substrate 1. The HT film 2 is, for example, a molybdenum silicon film (MoSi film). In this case, the HT film 2 may be formed of a silicon nitride film (SiN film), and as a result, may contain a Mo atom, a Si atom, and an N atom.

FIG. 1 shows a pattern portion P1 and a non-pattern portion P2 of the HT film 2. The pattern portion P1 and the non-pattern portion P2 are formed by processing the HT film 2 by etching to form the HT film pattern 2a. The pattern portion P1 is a portion in which the HT film 2 remains after the etching, and the non-pattern portion P2 is a portion in which the HT film 2 is removed during the etching. In other words, the pattern portion P1 is a portion corresponding to the HT film pattern 2a, and the non-pattern portion P2 is a portion corresponding to the recessed portion in the HT film 2.

The photomask according to the present embodiment is a halftone mask as described above. Therefore, the phase of the light transmitted through the substrate 1 and the pattern portion P1 is substantially 180 degrees different from the phase of the light transmitted through the substrate 1 and the non-pattern portion P2. That is, the HT film 2 according to the present embodiment has a function of substantially reversing the phase of light.

As shown in FIG. 1, the substrate 1 and the HT film 2 according to the present embodiment include a region R1 including the pattern portion P1 and the non-pattern portion P2, and another region R2 including the pattern portion P1 and the non-pattern portion P2. The light transmittance rate of the substrate 1 and the HT film 2 in the region R1 is different from the light transmittance rate of the substrate 1 and the HT film 2 in the region R2. For example, the light transmittance rate of the region R1 is a lower value, and the light transmittance rate of the region R2 is a higher value. The former value is an example of a first value, and the latter value is an example of a second value. A region having a lower light transmittance rate, such as the region R1, is referred to as a dark region (or dark mask). A region having a higher light transmittance rate, such as the region R2, is referred to as a bright region (or bright mask). Further details of the regions R1 and R2 will be described below.

The light transmittance rate described above is an energy transmittance rate indicating a ratio of energy of light after being transmitted to energy of light before being transmitted. Meanwhile, an amplitude transmittance rate indicates a ratio of an amplitude of light after being transmitted to an amplitude of light before being transmitted. The energy transmittance rate is a square of the amplitude transmittance rate. In the present specification, the energy transmittance rate is simply referred to as “transmittance rate” or “light transmittance rate.”

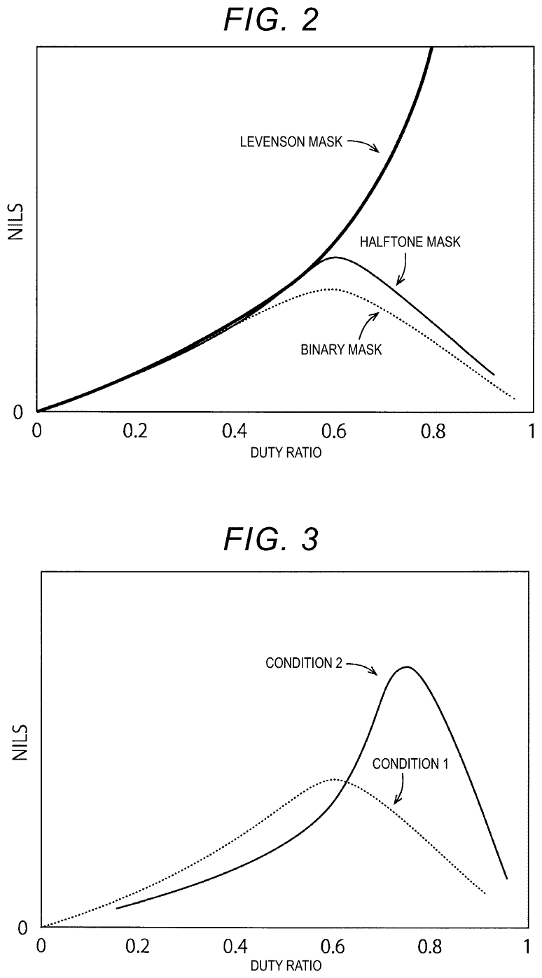

In addition, the substrate 1 and the HT film 2 according to the present embodiment may include three or more regions having different transmittance rates from each other. For example, the substrate 1 and the HT film 2 according to the present embodiment may include the region R1 having a lower transmittance rate, the region R2 having a higher transmittance rate, and another region having a transmittance rate between the transmittance rate of the region R1 and the transmittance rate of the region R2. FIG. 2 is a graph showing characteristics of photomasks of different types.

FIG. 2 shows a relationship between duty ratios of a binary mask, a halftone mask, and a Levenson mask and NILS values. The duty ratio corresponds to an area ratio of a pattern portion to a non-pattern portion of each photomask in a plan view. For example, when the area ratio of the pattern portion to the non-pattern portion is 3:1, the duty ratio is 0.75 (=3/4). The shapes of the pattern portion and the non-pattern portion of each photomask in FIG. 2 are the same as the shapes of the pattern portion P1 and the non-pattern portion P2 of the photomask shown in FIG. 1. The duty ratio of each photomask is also referred to as a coverage rate of a photomask pattern of each photomask. For example, the duty ratio of the photomask shown in FIG. 1 is also referred to as a coverage rate of the HT film pattern 2a. Meanwhile, the NILS value is defined by the slope of the logarithmic value of the light intensity, and is an indicator of the process margin of each photomask. As the NILS value is increased, the pattern dimension variation on a wafer with respect to the exposure amount variation is decreased, and thus the large NILS value corresponds to a large process margin.

According to FIG. 2, the process margin of the halftone mask is larger than the process margin of the binary mask. On the other hand, the process margin of the halftone mask is smaller than the process margin of the Levenson mask, but it is known that the Levenson mask has more design constraints than the halftone mask. In consideration of these relationships and the design constraints, in the present embodiment, a halftone mask is adopted as the photomask. As a result, it is possible to increase the process margin while reducing the design constraints.

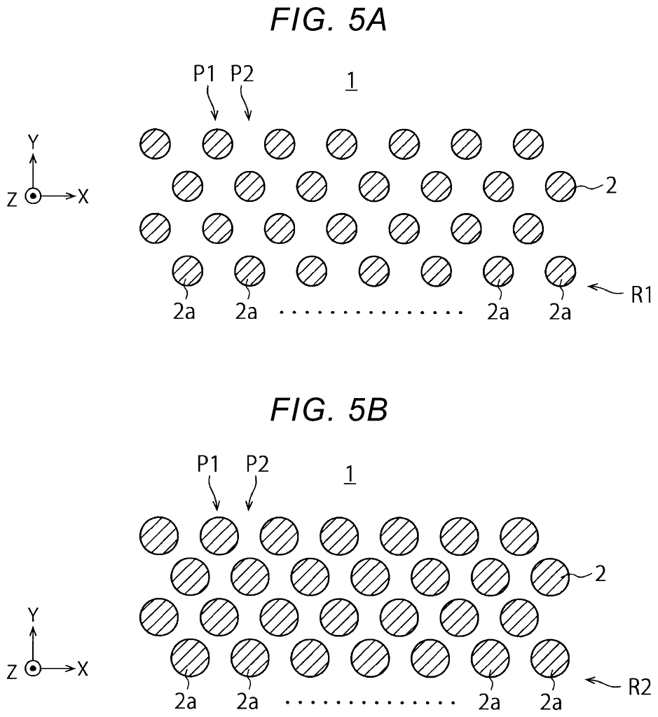

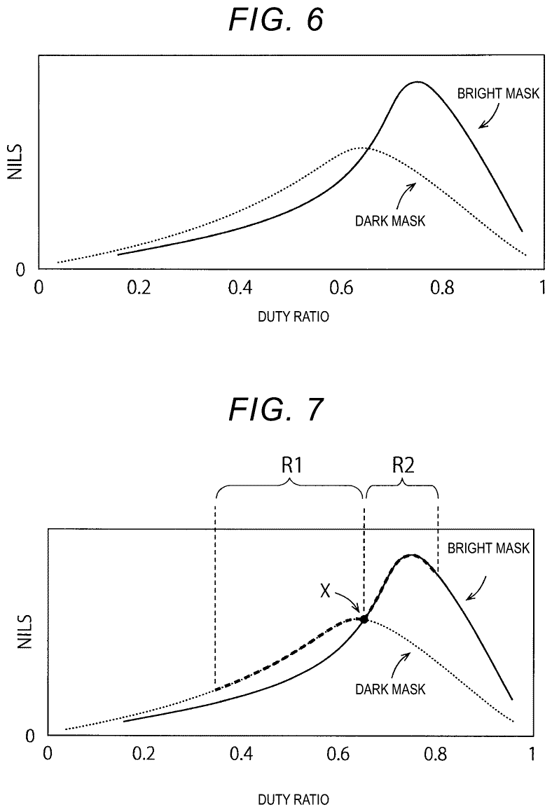

The term “duty ratio” is generally used when the photomask pattern is a periodic pattern. Examples of the periodic pattern are shown in FIGS. 4A to 5B, which will be described below. Meanwhile, the description of FIG. 2 may be applied even when the photomask pattern is an aperiodic pattern. The same applies to the following description in which the term “duty ratio” appears. Meanwhile, the term “coverage rate” may be generally used regardless of whether the photomask pattern is a periodic pattern or aperiodic pattern. Therefore, the term “duty ratio” appearing in the present specification may be replaced with the term “coverage rate”.

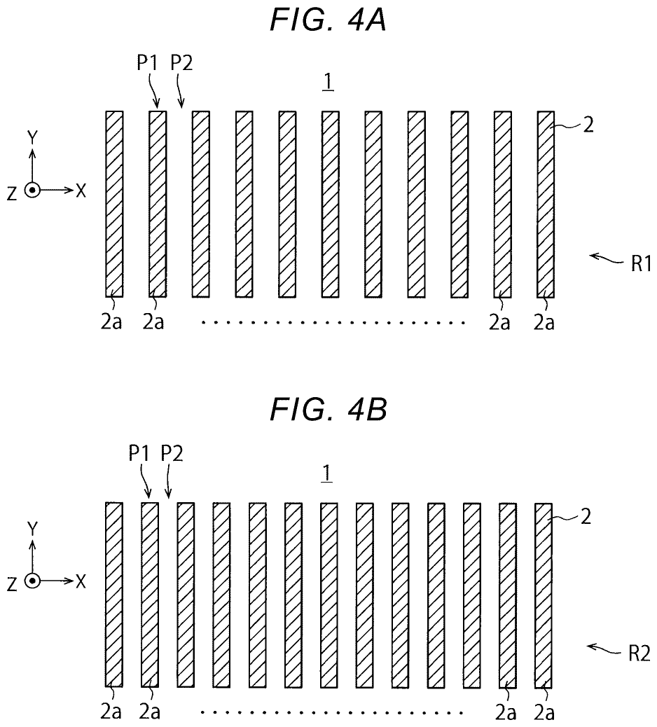

FIG. 3 is a graph showing characteristics of a halftone mask.

FIG. 3 shows a relationship between the duty ratio of the halftone mask and the NILS value in two conditions. One curve shows a relationship between the duty ratio and the NILS value when the lithography is performed under a condition 1, and the other curve shows a relationship between the duty ratio and the NILS value when the lithography is performed under a condition 2. For example, in the condition 1 and the condition 2, the exposure amounts during the lithography are different.

According to FIG. 3, it is desirable to perform the lithography under the condition 1 when the duty ratio of the halftone mask is small. On the other hand, it is desirable to perform the lithography under the condition 2 when the duty ratio of the halftone mask is large.

This is a problem when the duty ratio of the halftone mask is different for each region of the halftone mask. For example, when the halftone mask includes a region 1 having a smaller duty ratio and a region 2 having a larger duty ratio, it is desirable that the lithography using the region 1 is performed under the condition 1, and the lithography using the region 2 is performed under the condition 2. In this case, when the condition 1 is adopted, the process margin of the lithography using the region 2 is smaller than the process margin when the condition 2 is adopted. On the other hand, when the condition 2 is adopted, the process margin of the lithography using the region 1 is smaller than the process margin when the condition 1 is adopted. Since the region 1 and the region 2 are provided in the same halftone mask, it is not desirable to use the halftone mask for exposure under different conditions, and it is desirable to use the halftone mask for exposure under the same condition. When the same condition can be suitably adopted for the region 1 and the region 2, the region 1 and the region 2 may be used for the exposure at the same time under the same condition while increasing the process margin of the region 1 and the region 2.

The photomask shown in FIG. 1 also includes two regions, that is, the region R1 and the region R2, as described above. Therefore, when the duty ratio of the region R1 is smaller and the duty ratio of the region R2 is larger, the same problem as the region 1 and the region 2 described above may occur. However, in the present embodiment, the transmittance rate of the region R1 is a lower value, and the transmittance rate of the region R2 is a higher value. As a result, it is possible to reduce the above problem. The details will be described below.

FIGS. 4A and 4B illustrate plan views of an example of the photomask patterns according to the first embodiment.

FIGS. 4A and 4B show examples of the region R1 and the region R2 according to the present embodiment, respectively. The region R1 includes the HT film pattern 2a for forming the line and space (L/S) pattern. This HT film pattern 2a is used, for example, to form a word line of a two-dimensional NAND memory. The same applies to the region R2. Meanwhile, the width of the pattern portion P1 in the region R2 is the same as the width of the pattern portion P1 in the region R1, and the width of the non-pattern portion P2 in the region R2 is narrower than the width of the non-pattern portion P2 in the region R1. As a result, the duty ratio of the region R2 is larger than the duty ratio of the region R1.

FIGS. 5A and 5B illustrate plan views of another example of the photomask patterns according to the first embodiment.

FIGS. 5A and 5B show examples of the region R1 and the region R2 according to the present embodiment, respectively. The region R1 includes the HT film pattern 2a for forming the hole pattern. The HT film pattern 2a is used, for example, to form memory holes of a three-dimensional NAND memory. The same applies to the region R2. Meanwhile, the pitch between the pattern portions P1 in the region R2 is the same as the pitch between the pattern portions P1 in the region R1, and the diameter of the pattern portion P1 in the region R2 is larger than the diameter of the pattern portion P1 in the region R1. As a result, the duty ratio of the region R2 is larger than the duty ratio of the region R1.

The photomask pattern (i.e., HT film pattern 2a) according to the present embodiment may have the shape shown in FIG. 4A and FIG. 4B, may have the shape shown in FIG. 5A and FIG. 5B, or may have other shapes.

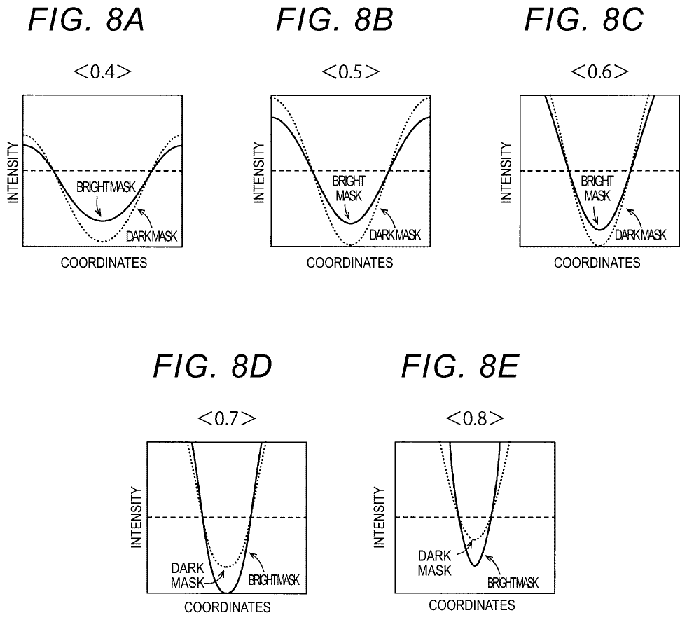

FIGS. 6 to 9B are graphs to explain a design manner of the photomask according to the first embodiment.

FIG. 6 shows a relationship between the duty ratio of a halftone mask and the NILS value in two cases. One curve shows a relationship between the duty ratio and the NILS value when the halftone mask is a dark mask, and the other curve shows a relationship between the duty ratio and the NILS value when the halftone mask is a bright mask. As described above, the transmittance rate of the dark mask is lower than the transmittance rate of the bright mask. In FIG. 6, the transmittance rate of the dark mask is about 0.49 times the transmittance rate of the bright mask, and the amplitude transmittance rate of the dark mask is about 0.7 times the amplitude transmittance rate of the bright mask.

The relationship between the two curves shown in FIG. 6 is similar to the relationship between the two curves shown in FIG. 3. This means that the change of the condition 2 to the condition 1 has the same effect as the replacement of the bright mask with the dark mask. In FIG. 3, an example in which the lithography using the region 1 where the duty ratio is smaller is desirably performed under the condition 1, and the lithography using the region 2 where the duty ratio is larger is desirably performed under the condition 2 is described. According to FIG. 6, the effect of this example is also obtained by performing the lithography using the region 1 and region 2, in which the region 1 is set as the dark mask and the region 2 is set as the bright mask, under the condition 2. As a result, it is possible to improve the process margin of the lithography using the region 1 and the process margin of the lithography using the region 2 under the same condition, that is, the condition 2. Therefore, the region 1 and the region 2 provided in the same halftone mask can be suitably used for exposure under the same condition.

In order to obtain such an advantage, the regions R1 and R2 shown in FIG. 1 are the dark mask (dark region) and the bright mask (bright region), respectively. That is, the region R1 in which the duty ratio is smaller is a dark mask, and the region R2 in which the duty ratio is larger is a bright mask.

FIG. 7 shows the two curves, which are the same as those in FIG. 6, and the intersection X of these curves. When the NILS value of the dark mask and the NILS value of the bright mask are compared at the same duty ratio, in a range where the duty ratio is lower than the duty ratio of the intersection X, the NILS value of the dark mask is higher than the NILS value of the bright mask. On the other hand, in a range where the duty ratio is higher than the duty ratio of the intersection X, the NILS value of the bright mask is higher than the NILS value of the dark mask.

FIG. 7 can be further used to explain the setting method of the regions R1 and R2. In the present embodiment, when the duty ratio in a certain region is lower than the duty ratio of the intersection X, the region is set as a dark mask. On the other hand, when the duty ratio in a certain region is higher than the duty ratio of the intersection X, the certain region is set as a bright mask. As a result, the region having the duty ratio lower than the duty ratio of the intersection X is set as the region R1, and the region having the duty ratio higher than the duty ratio of the intersection X is set as the region R2. As a result, it is possible to improve the process margin of the lithography using the region R1 and the process margin of the lithography using the region R2 under the same condition. Therefore, the region R1 and the region R2 provided in the same photomask according to the present embodiment can be suitably used for exposure under the same condition. The duty ratio of the intersection X is an example of a threshold value of the coverage rate.

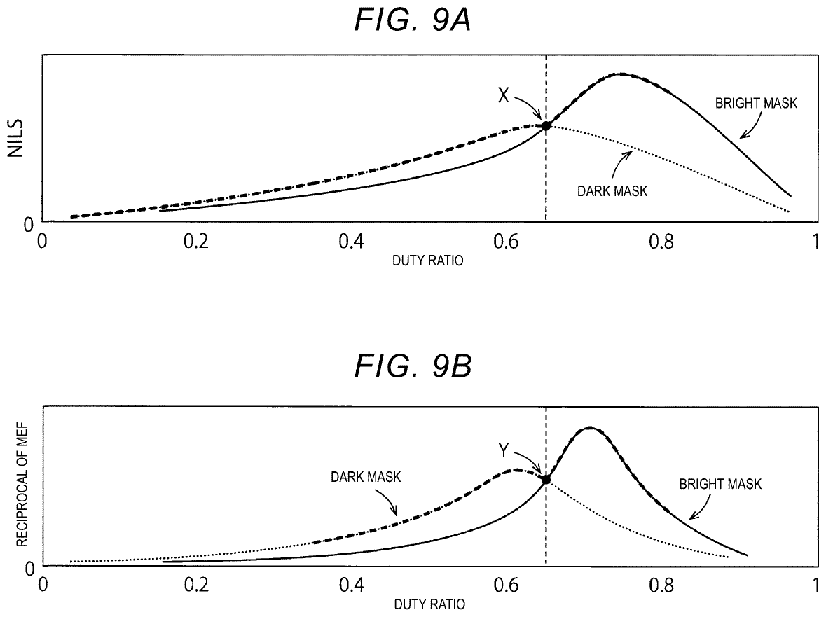

FIGS. 8A to 8E show the latent image intensity distributions when the dark mask and the bright mask having a duty ratio of 0.4 to 0.8 are used. Broken lines shown in FIGS. 8A to 8E indicate slice levels. The transmittance rate of the dark mask and the transmittance rate of the bright mask are the same as in the case of FIGS. 6 and 7.

It is desirable that the latent image intensity distribution is steep. This is because, when the latent image intensity distribution is steep, a boundary between the positive part and the negative part of the resist film is clear. According to FIGS. 8A to 8E, a region in which the duty ratio is 0.4 to 0.6 is desirably a dark mask, and a region in which the duty ratio is 0.7 to 0.8 is desirably a bright mask. This result is consistent with the result shown in FIG. 6.

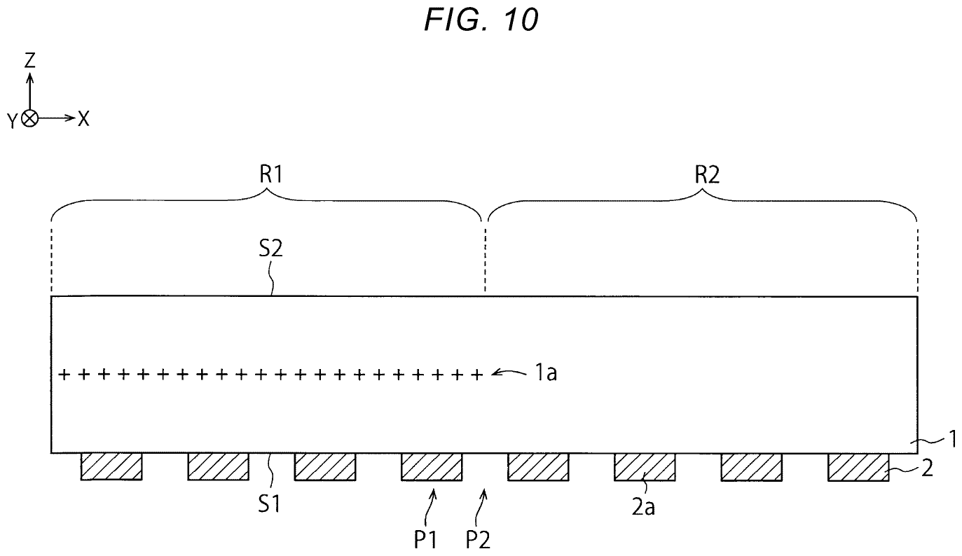

FIG. 9A shows the relationship between the duty ratio and the NILS value for the dark mask and the bright mask, as in FIG. 7. FIG. 9B shows a relationship between the duty ratio and a reciprocal of a mask error factor (MEF) value for the dark mask and the bright mask. The MEF value is a ratio at which a dimensional error on each photomask is magnified on an exposed wafer, and is an indicator of the mask specification of each photomask. As the MEF value is increased, the dimension variation on the wafer with respect to the dimensional error on the photomask is reduced, and thus a large reciprocal of the MEF value means that a large process margin of the mask specification can be allowed. The duty ratio of the intersection Y of the two curves shown in FIG. 9B is the same as the duty ratio of the intersection X of the two curves shown in FIG. 9A. According to FIG. 9B, it can be seen that the MEF value is also improved by improving the NILS value according to the present embodiment.

As described above, the substrate 1 and the HT film 2 of the photomask according to the present embodiment include the region R1 (dark mask) having a lower transmittance rate and the region R2 (bright mask) having a higher transmittance rate. For example, the HT film pattern 2a in the region R1 has a lower duty ratio, and the HT film pattern 2a in the region R2 has a higher duty ratio. According to the present embodiment, by setting the transmittance rate of the region R1 and the transmittance rate of the region R2 to different values, it is possible to improve both the process margin of the lithography using the region R1 and the process margin of the lithography using the region R2. For example, the region R1 and the region R2 provided on the same photomask and having different duty ratios can be suitably used for exposure under the same condition.

### Second Embodiment

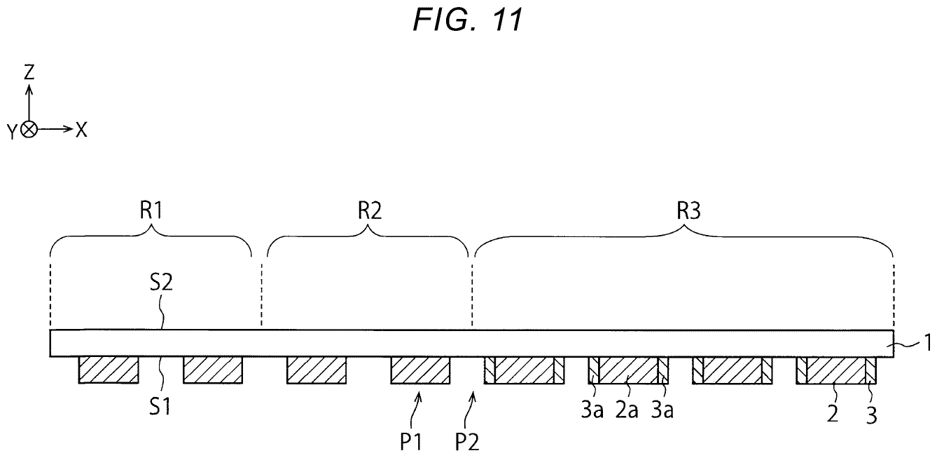

FIG. 10 illustrates a cross-sectional view of a photomask according to the second embodiment.

The photomask according to the present embodiment includes a plurality of shading elements 1a provided in the substrate 1 in addition to the elements of the photomask according to the first embodiment. Hereinafter, the shading elements 1a may be collectively referred to as a shading pattern. In the present embodiment, the shading elements 1a are provided only in the region R1 among the regions R1 and R2, and are provided in a planar shape parallel to the XY plane in the region R1. In FIG. 10, each shading element 1a is schematically shown by a sign “+”.

The shading element 1a has a function of reducing a transmittance rate in the substrate 1. In the present embodiment, the shading element 1a is provided only in the region R1, so that the transmittance rate of the region R1 is lower than the transmittance rate of the region R2. For example, the transmittance rate of the substrate 1 in the region R2 is about 100%, the transmittance rate of the substrate 1 in the region R1 is about 49%, and the transmittance rate of the mask film 2 in the regions R1 and R2 is about 6%. As a result, the ratio of the transmittance rate of the region R1 to the transmittance rate of the region R2 is 49×6:100×6, and the transmittance rate of the region R1 is 0.49 times the transmittance rate of the region R2.

Alternatively, the shading elements 1a may also be provided in the region R2. For example, the shading elements 1a in the region R2 is provided in the substrate 1 in a planar shape parallel to the XY plane, similarly to the shading elements 1a in the region R1. In this case, the density of the shading elements 1a in the region R2 is set to be lower than the density of the shading elements 1a in the region R1. As a result, it is possible to set the transmittance rate of the region R1 to be lower than the transmittance rate of the region R2. It should be noted that, a case where the shading elements 1a are not provided in the region R2 as in the present embodiment corresponds to a case where the density of the shading elements 1a in the region R2 is zero.

The shading elements 1a at a certain location in the substrate 1 are formed, for example, by irradiating the location in the substrate 1 with a laser. When the substrate 1 is irradiated with the laser, the material of the substrate 1 undergoes a phase transition, and the shading elements 1a are formed in the substrate 1. An example of such a laser is a femtosecond laser.

It is desirable that a distance between the surface S1 of the substrate 1 and the shading elements 1a in the substrate 1 is small. The reason is that there is a risk that the latent image is blurred when the distance is large. The distance is, for example, 166 μm to 500 μm.

As described above, the photomask according to the present embodiment includes the shading elements 1a in the substrate 1. Therefore, according to the present embodiment, it is possible to set the transmittance rate of the region R1 and the transmittance rate of the region R2 to values different from each other using the shading elements 1a.

The transmittance rate of the substrate 1 may be adjusted using an element other than the shading elements 1a. For example, the transmittance rate of the substrate 1 may be adjusted by forming an uneven pattern on the surface of the substrate 1.

### Third Embodiment

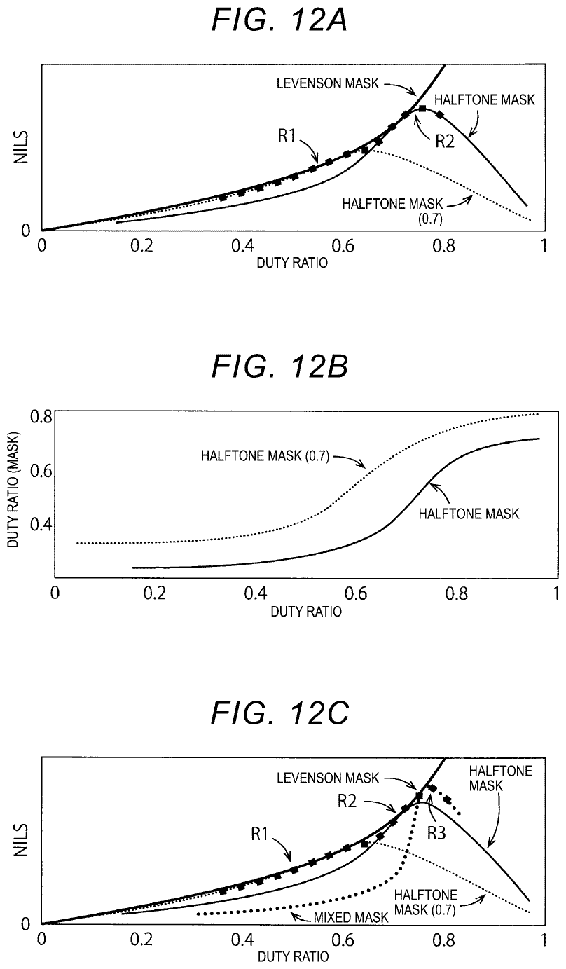

FIG. 11 illustrates a cross-sectional view of a photomask according to a third embodiment.

The photomask of the present embodiment includes the phase shifter film 3 formed on the surface S1 of the substrate 1 in addition to the elements of the photomask according to the first embodiment. The phase shifter film 3 includes a phase shifter film pattern 3a which forms a photomask pattern together with the HT film 2. The phase shifter film pattern 3a is formed on side surfaces of the HT film pattern 2a. In the present embodiment, the phase of the light transmitted through the substrate 1 and the phase shifter film 3 is substantially 180 degrees different from the phase of the light transmitted through the substrate 1 and the HT film 2. The phase shifter film 3 is an example of a mask film, similarly to the HT film 2.

The substrate 1, the HT film 2, and the phase shifter film 3 according to the present embodiment include the region R1, the region R2, and a region R3. Each of the regions R1 to R3 includes the pattern portion P1 and the non-pattern portion P2. The regions R1 and R2 include the substrate 1 and the HT film 2, but do not include the phase shifter film 3. The regions R1 and R2 are the dark mask and the bright mask, respectively, as in the regions R1 and R2 according to the first embodiment. The duty ratio of the region R1 is smaller, and the transmittance rate of the region R1 is lower. The duty ratio of the region R2 is larger, and the transmittance rate of the region R2 is higher.

The region R3 includes the substrate 1, the HT film 2, and the phase shifter film 3. Therefore, the pattern portion P1 in the region R3 includes the HT film 2 and the phase shifter film 3. In the region R3, the pattern portion P1 is a portion corresponding to the HT film pattern 2a and the phase shifter film pattern 3a, and the non-pattern portion P2 is a portion corresponding to the recessed portions in the HT film 2 and the phase shifter film 3. In the present embodiment, the duty ratio of the region R3 is larger than the duty ratio of the region R2, and the transmittance rate of the region R3 is the same as the transmittance rate of the region R2. The transmittance rate of the region R3 is the transmittance rate of light of the substrate 1, the HT film 2, and the phase shifter film 3 in the region R3. The region R3 is an example of a third region.

The regions R1 and R2 include the substrate 1 and the HT film 2, and have a halftone mask structure. Meanwhile, the region R3 has a structure in which the phase shifter film 3 is added to the halftone mask, and has a structure similar to the Levenson mask or the attenuating phase shift mask. In the following description, the photomask having the structure of the region R3 will be referred to as a mixed mask.

As described above with reference to FIG. 2, the Levenson mask has suitable characteristics. According to the present embodiment, it is possible to perform more suitable lithography by incorporating the element of the Levenson mask into the halftone mask.

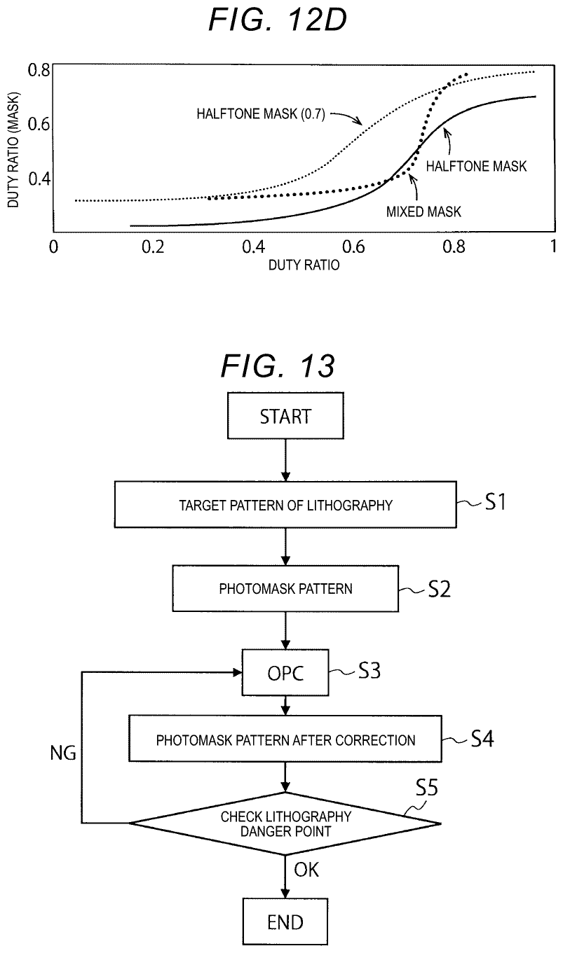

FIGS. 12A to 12D are graphs showing characteristics of photomasks to design the photomask according to the third embodiment.

FIG. 12A shows the NILS values of the halftone mask corresponding to the dark mask, the halftone mask corresponding to the bright mask, and the Levenson mask. Here, the amplitude transmittance rate of the dark mask is 0.7 times the amplitude transmittance rate of the bright mask. Further, in FIG. 12A, the NILS value of the photomask according to the first embodiment including the dark mask and the bright mask is shown by the thick broken line. The photomask according to the present embodiment has a dark mask structure in the region R1 and has a bright mask structure in the region R2. FIG. 12B shows a relationship between the mask duty ratio of the halftone mask corresponding to the dark mask and the mask duty ratio of the halftone mask corresponding to the bright mask. In FIG. 12B, the horizontal axis indicates the duty ratio of the patterned resist formed on the wafer, and the vertical axis indicates the duty ratio of the mask pattern.

FIG. 12C shows the NILS value of the mixed mask in addition to the NILS value shown in FIG. 12A. FIG. 12C further shows the NILS values of the photomask according to the present embodiment including the dark mask, the bright mask, and the mixed mask by the thick broken line. According to FIG. 12C, the NILS value of the mixed mask is increased in the range where the duty ratio is large. Therefore, the photomask according to the present embodiment has the dark mask structure in the region R1 having a small duty ratio, has the bright mask structure in the region R2 having a medium duty ratio, and has a mixed mask structure in the region R3 having a large duty ratio. As a result, it is possible to perform the lithography more suitable than the lithography according to the first embodiment. FIG. 12D shows a relationship with the mask duty ratio of the mixed mask in addition to the mask duty ratios shown in FIG. 12B. In FIG. 12D, the horizontal axis indicates the duty ratio of the patterned resist formed on the wafer, and the vertical axis indicates the duty ratio of the mask pattern.

As described above, the photomask according to the present embodiment includes the region R1 corresponding to the dark mask, the region R2 corresponding to the bright mask, and the region R3 corresponding to the mixed mask. Therefore, according to the present embodiment, it is possible to perform the lithography more suitable than the lithography when a photomask including only the regions R1 and R2 is used.

The transmittance rate of the region R3 is the same as the transmittance rate of the region R2 in the present embodiment, but may be the same as the transmittance rate of the region R1 or may be different from the transmittance rate of the regions R1 and R2.

### Fourth Embodiment

In a fourth embodiment, a method of designing a photomask pattern for manufacturing a photomask will be described. For example, when manufacturing the photomask shown in FIG. 1, a layout of the photomask pattern (HT film pattern 2a) shown in FIG. 1 is designed. In this case, the photomask shown in FIG. 1 is manufactured by processing the HT film 2 into the HT film pattern 2a according to the designed photomask pattern.

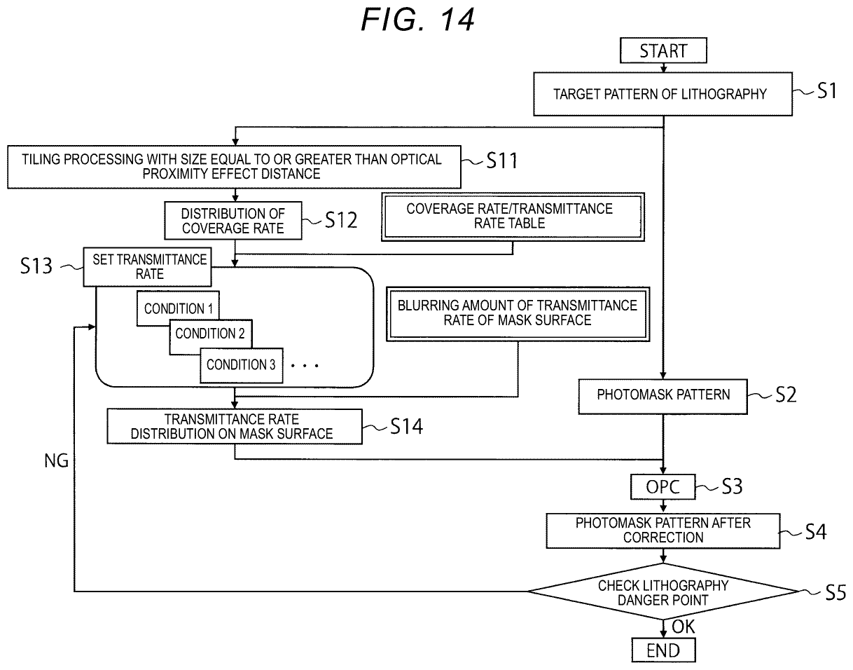

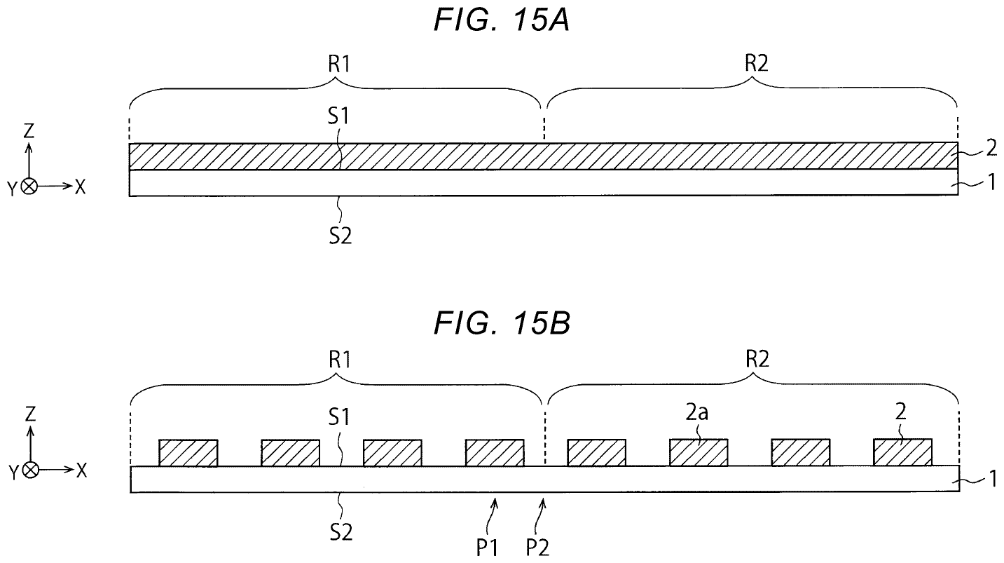

Hereinafter, as a premise for describing a design method (FIG. 14) of a photomask pattern according to the fourth embodiment, a design method (FIG. 13) of a photomask pattern according to a comparative example of the fourth embodiment will be described.

FIG. 13 is a flowchart showing a design method of a photomask pattern according to a comparative example of the fourth embodiment. In the design method according to the present comparative example, a photomask pattern for a halftone mask corresponding to the bright mask is designed.

First, data of a target pattern of the lithography is acquired (step S1). For example, when the semiconductor layer or the metal layer is processed using lithography and etching to form word lines of a two-dimensional NAND memory, data of a pattern of the word lines is acquired.

Next, the data of the photomask pattern is created using the data of the target pattern of the lithography (step S2). For example, data of a photomask pattern for manufacturing a photomask for word lines is created. Examples of such a photomask pattern are shown in FIGS. 4A and 4B.

Next, the data of the photomask pattern is corrected using optical proximity correction (OPC) or the like (step S3). For example, a sub-resolution assist feature (SRAF) pattern is added to a photomask pattern for word lines.

Next, the corrected data of the photomask pattern is output (step S4). For example, data of a photomask pattern including an L/S pattern for word lines and an SRAF pattern for OPC is output. When the method of the present comparative example is executed by a computer, such as a personal computer (PC), the data of the photomask pattern is output in a form of, for example, displaying the photomask pattern on a display, storing the data of the photomask pattern in a storage, or transmitting the data of the photomask pattern to another device.

Next, a lithography danger point of the photomask pattern is checked using the corrected data of the photomask pattern (step S5). The lithography danger point is a location where the lithography is likely to be incorrectly performed. When the lithography danger point is not detected, the method of the present comparative example is ended.

On the other hand, when the lithography danger point is detected, re-correction is performed on the corrected data of the photomask pattern using the OPC or the like (step S3). The re-correction is performed with an aim of eliminating the lithography danger point. Next, the photomask pattern is output as the re-corrected data (step S4). Next, the lithography danger point of the photomask pattern is checked by using the data of the re-corrected photomask pattern (step S5). The subsequent processing is the same as the processing after the first correction.

FIG. 14 is a flowchart showing a design method of a photomask pattern according to the fourth embodiment. In the method according to the present embodiment, the photomask according to the first embodiment, that is, a photomask pattern for a halftone mask, which includes the region R1 corresponding to the dark mask and the region R2 corresponding to the bright mask, is designed.

The method according to the present embodiment includes steps S11 to S14 in addition to steps S1 to S5 described in the comparative example above. The method according to the present embodiment is executed by a computer, such as a PC, in the same manner as in the method according to the comparative example described above.

In the present embodiment, not only step S2 but also step S11 is performed after step S1. Specifically, tiling processing for calculating the coverage rate distribution of the target pattern is performed (step S11). In the tiling processing, the target pattern is divided into a plurality of square regions in a two-dimensional array using a grid (mesh). These square regions are referred to as tiles. In the tiling processing according to the present embodiment, the dimensions of the grid are set to be equal to or greater than an optical proximity effect (OPE) distance, which is a distance that affects the OPC. That is, the length of one side of the tile is set to be equal to or greater than the OPE distance. The shape of the tile may be other than a square (for example, a rectangle or a triangle).

Next, the coverage rate distribution of the target pattern is calculated using these tiles (step S12). In the present embodiment, the coverage rate distribution of the target pattern is calculated by calculating the coverage rate of the target pattern in each tile. The coverage rate of the target pattern of each tile is a ratio of the area of the target pattern to the area of each tile, and corresponds to the above-described duty ratio. In the present embodiment, the coverage rate of the target pattern in each tile is the coverage rate (duty ratio) of the photomask pattern in the region corresponding to each tile. Therefore, in steps S11 and S12, the photomask pattern may be divided into a plurality of tiles, and the coverage rate of the photomask pattern of each tile may be calculated.

Next, a condition for setting the transmittance rate of the photomask is created based on the coverage rate distribution of the target pattern (step S13). For example, when the coverage rate of a certain tile is smaller than the coverage rate of the intersection X (FIG. 7) which is the threshold value, a condition in which the transmittance rate of the region corresponding to the tile is set to a low value is created. This region is included in the above-described region R1. In addition, when the coverage rate of a certain tile is larger than the coverage rate of the intersection X (FIG. 7) which is the threshold value, a condition in which the transmittance rate of the region corresponding to the tile is set to a high value is created. This region is included in the above-described region R2. In the present embodiment, these conditions are created based on a table showing a relationship between the coverage rate and the transmittance rate. The number of created conditions may be any applicable number. In the present embodiment, as shown in FIG. 7, the method of setting two types of transmittance rates with one intersection X as a boundary based on the data of two types of transmittance rates is shown. Alternatively, for example, three types of transmittance rates may be set with two intersections as boundaries based on the data of three types of transmittance rates.

Next, based on these conditions, the transmittance rate distribution on the mask surface, that is, the two-dimensional transmittance rate distribution of the photomask is calculated (step S14). In the present embodiment, the transmittance rate distribution of the photomask is calculated by calculating the transmittance rate of the photomask in the region corresponding to each tile. As a result, the distribution of the region R1 or the distribution of the region R2 is created. For example, a region having a low coverage rate is included in the region R1, and a low transmittance rate is set. In addition, a region having a high coverage rate is included in the region R2, and a high transmittance rate is set. The processing of step S14 may be performed by considering the blurring amount of the transmittance rate of the mask surface.

The processing of setting the low transmittance rate to the region R1 and setting the high transmittance rate to the region R2 in steps S13 and S14 may be performed in any applicable manner. For example, when the default value of the transmittance rate of the above-described substrate 1 is 100%, the transmittance rate of the substrate 1 may be maintained at 100% in the region R2, and the transmittance rate of the substrate 1 may be reduced from 100% to 49% in the region R1. As a result, it is possible to manufacture a photomask as in the second embodiment. Such a reduction in the transmittance rate can be achieved, for example, by using the above-described shading elements 1a. In steps S13 and S14, only the transmittance rate of the region R2 may be changed, or the transmittance rate of both the region R1 and the region R2 may be changed.

Next, the data of the photomask pattern is corrected using the OPC or the like (step S3), and the corrected data of the photomask pattern is output (step S4). The correction in step S4 of the present embodiment is performed in consideration of the transmittance rate of each tile calculated in step S14. Therefore, the data after the correction includes the data related to the distribution of the transmittance rate calculated in step S14. As a result, it is possible to manufacture the photomask including the regions R1 and R2 having different transmittance by rates manufacturing the photomask according to the data after the correction.

Next, the lithography danger point of the photomask pattern is checked using the corrected data of the photomask pattern (step S5). When the lithography danger point is not detected, the method according to the present embodiment is ended.

On the other hand, when the lithography danger point is detected, the processing of steps S13, S14, S3, and S4 is performed again. For example, the re-correction in step S3 is performed with the aim of eliminating the lithography danger point. In addition, when the coverage rate of a certain region is increased using the OPC, in step S14, the transmittance rate of the region may be changed from a lower value to a higher value. On the contrary, when the coverage rate of a certain region is lowered using the OPC, in step S14, the transmittance rate of the region may be changed from a higher value to a lower value. As a result, the shapes of the regions R1 and R2 are changed. In addition, in step S13, one or both of the transmittance rate of the region R1 and the transmittance rate of the region R2 may be changed. For example, in the above-described example in which the transmittance rate of the substrate 1 in the region R1 is reduced from 100% to 49%, the value of 49% may be changed to another value (for example, 36%). As described above, when the lithography danger point is detected, in step S14, the distribution or the transmittance rate of the regions R1 and R2 may be edited (changed).

Next, the photomask pattern is output as the re-corrected data (step S4). Next, the lithography danger point of the photomask pattern is checked by using the data of the re-corrected photomask pattern (step S5). The subsequent processing is the same as the processing after the first correction.

As described above, in the present embodiment, the coverage rate distribution of the target pattern or the mask pattern is calculated, and the data of the photomask pattern including the region R1 having the lower transmittance rate and the region R2 having the higher transmittance rate is created based on the coverage rate distribution. For example, the region R1 has a lower coverage rate, and the region R2 has a higher coverage rate. According to the present embodiment, by setting the transmittance rate of the region R1 and the transmittance rate of the region R2 to different values, it is possible to improve both the process margin of the lithography using the region R1 and the process margin of the lithography using the region R2.

The correction in step S4 of the present embodiment may be performed using an inverse lithography technology (ILT) instead of using OPC. In addition, the table referred to in step S13 of the present embodiment may include a correspondence relationship between the coverage rate and the transmittance rate. For example, this table may include a correspondence relationship indicating that “when the coverage rate of a certain region is a value V1, the value of the transmittance rate of the region is V2”. On the other hand, in step S13 of the present embodiment, the condition may be set using simulation or numerical calculation. In addition, the photomask pattern according to the present embodiment may be a photomask pattern for manufacturing the photomask according to the second or third embodiment.

### Fifth Embodiment

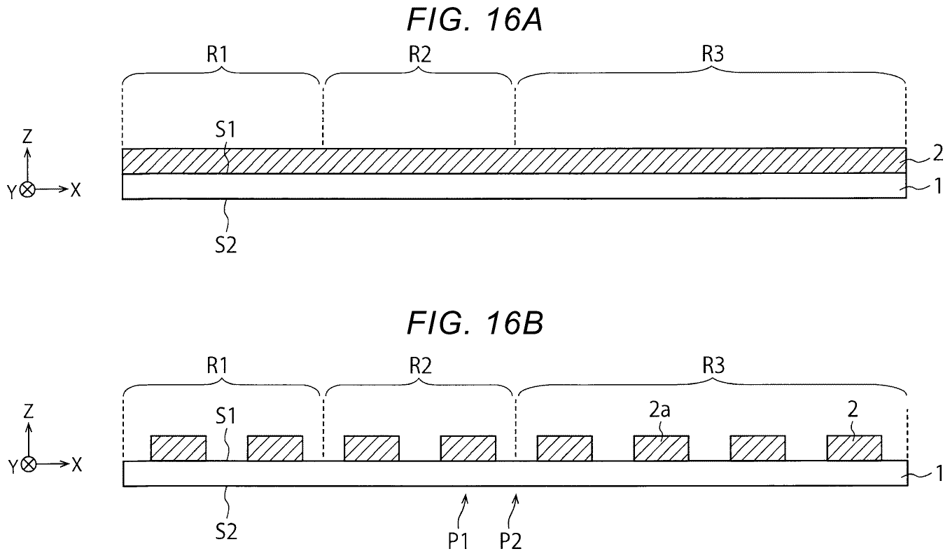

FIGS. 15A and 15B are cross-sectional diagrams showing a manufacturing method of the photomask according to the fifth embodiment. FIGS. 15A and 15B show a process of manufacturing a photomask according to the first embodiment.

First, the substrate 1 is prepared (FIG. 15A). In FIG. 15A, the surface S1 of the substrate 1 is the upper surface of the substrate 1, and the surface S2 of the substrate 1 is the lower surface of the substrate 1. Next, the HT film 2 is formed on the surface S1 of the substrate 1 (FIG. 15A).

Next, the HT film 2 is processed using lithography and reactive ion etching (RIE) to form the HT film pattern 2a using the HT film 2 (FIG. 15B). As a result, the pattern portion P1 and the non-pattern portion P2 are formed in the HT film 2.

The substrate 1 and the HT film 2 shown in FIG. 15B include regions R1 and R2. As described above, the region R1 has a lower duty ratio (i.e., coverage rate) and a lower transmittance rate. On the other hand, the region R2 has a higher duty ratio (i.e., coverage rate) and a higher transmittance rate. Such regions R1 and R2 can be formed by manufacturing a photomask using the data of the photomask pattern designed in the fourth embodiment.

The processing of reducing the transmittance rate of the region R1 and increasing the transmittance rate of the region R2 may be performed by any applicable method. For example, such a transmittance rate may be achieved by forming the above-described shading element 1a in the substrate 1. The shading element 1a will be described in detail in a seventh embodiment described below.

According to the present embodiment, it is possible to improve the process margin of the lithography by manufacturing the photomask according to the first embodiment.

### Sixth Embodiment

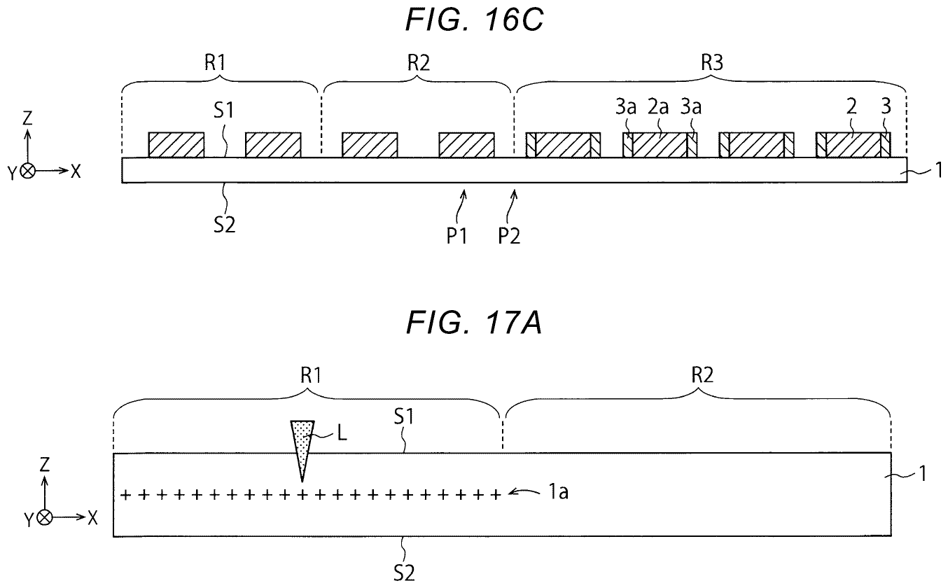

FIGS. 16A to 16C are cross-sectional diagrams showing the manufacturing method of a photomask according to a sixth embodiment. FIGS. 16A to 16C show a process of manufacturing a photomask according to the third embodiment. The steps shown in FIGS. 16A and 16B are carried out in the same manner as the steps in FIGS. 15A and 15B, respectively. FIGS. 16A and 16B show the region R3 in addition to the regions R1 and R2.

Next, the phase shifter film 3 including the phase shifter film pattern 3a is formed only in the region R3 among the regions R1 to R3 (FIG. 16C). The phase shifter film pattern 3a is formed, for example, by processing the phase shifter film 3 such that the phase shifter film 3 is formed in the regions R1 to R3, then the phase shifter film 3 is removed from the regions R1 and R2, and the phase shifter film 3 remains in the region R3. In this manner, the photomask according to the third embodiment is manufactured.

According to the present embodiment, it is possible to improve the process margin of the lithography by manufacturing the photomask according to the third embodiment.

### Seventh Embodiment

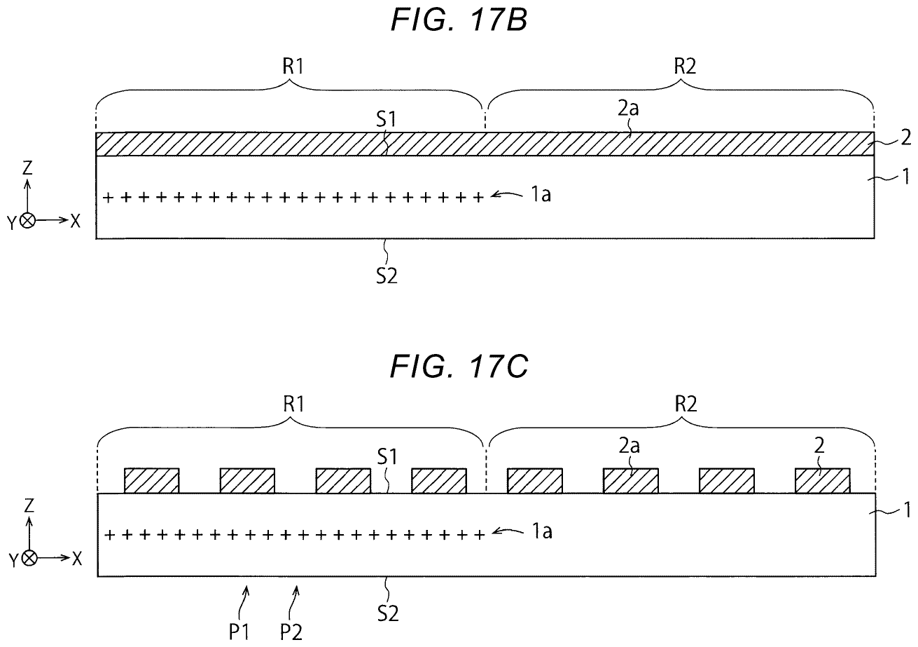

FIGS. 17A to 17C are cross-sectional diagrams showing the manufacturing method of a photomask according to the seventh embodiment. FIGS. 17A to 17C show a process of manufacturing a photomask according to the second embodiment.

First, the substrate 1 is prepared (FIG. 17A). Next, the substrate 1 is irradiated with the laser L to form a plurality of the shading elements 1a in the substrate 1 (FIG. 17A). The shading elements 1a according to the present embodiment are formed only in the region R1 among the regions R1 and R2. The laser L is, for example, a femtosecond laser.

Next, the HT film 2 is formed on the surface S1 of the substrate 1 (FIG. 17B). Next, the HT film 2 is processed using the lithography and the RIE to form the HT film pattern 2a using the HT film 2 (FIG. 17C). As a result, the pattern portion P1 and the non-pattern portion P2 are formed in the HT film 2.

According to the present embodiment, it is possible to improve the process margin of the lithography by manufacturing the photomask according to the second embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method of manufacturing a photomask comprising:
forming a mask film on a surface of a substrate; and
forming, with the mask film, a first mask pattern in a first region of the substrate and a second mask pattern in a second region of the substrate, wherein
a coverage ratio of the first mask pattern is different from a coverage ratio of the second mask pattern, and
a light transmittance rate of light through the substrate in the first region and the first mask pattern is different from a light transmittance rate of the light through the substrate in the second region and the second mask pattern.

2. The method according to claim 1, wherein
the coverage ratio of the first mask pattern is less than the coverage ratio of the second mask pattern, and
the light transmittance rate of the light through the substrate in the first region and the first mask pattern is less than the light transmittance rate of the light through the substrate in the second region and the second mask pattern.

3. The method according to claim 2, wherein the substrate in the first region has a first light transmittance rate and the substrate in the second region has a second light transmittance rate greater than the first light transmittance rate.

4. The method according to claim 3, further comprising:
processing the substrate to cause the first light transmittance rate to be less than the second light transmittance rate.

5. The method according to claim 4, wherein said processing comprises forming a shading pattern in the substrate.

6. The method according to claim 5, wherein a density of the shading pattern in the second region is less than a density of the shading pattern in the first region.

7. The method according to claim 4, further comprising:
generating photomask pattern data indicating the first light transmittance rate in the first region and the second light transmittance rate in the second region,
wherein the substrate is processed in accordance with the generated photomask pattern data.

8. The method according to claim 7, wherein said generating the photomask pattern data comprises:
generating data of a photomask pattern based on the data of the target pattern to be formed with the photomask;
determining a distribution of coverage ratios in the photomask pattern based on the generated data of the photomask pattern;
determining the distribution of light transmittance rates in a surface area of the photomask based on the determined distribution of coverage ratios in the photomask pattern;
correcting the data of the photomask pattern using the determined distribution of light transmittance rates, to generate the photomask pattern data.

9. The method according to claim 8, wherein said correcting is performed by optical proximity correction.

10. The method according to claim 9, wherein said determining the distribution of coverage ratios comprises determining a coverage ratio with respect to each of a plurality of grid regions of the photomask pattern, each of the grid regions having a dimension equal to or greater than an optical proximity effect distance that affects the optical proximity correction.

11. The method according to claim 8, wherein said correcting is performed in accordance with an inverse lithography technology.

12. The method according to claim 8, wherein said generating the photomask pattern data further comprises:
detecting a lithography danger point of the photomask pattern from the corrected data of the photomask pattern;
re-correcting the corrected data of the photomask pattern when the lithography danger point is detected,
wherein the photomask pattern data is generated from the re-corrected data of the photomask pattern.

13. The method according to claim 1, wherein the mask film includes a halftone film.

14. The method according to claim 13, wherein the mask film further includes a phase shifter film.

15. The method according to claim 14, further comprising:
forming, with the mask film, a third mask pattern in a third region of the substrate, wherein
the first mask pattern is formed with the halftone film and not with the phase shifter film,
the second mask pattern is formed with the halftone film and not with the phase shifter film, and
the third mask pattern is formed with the halftone film and the phase shifter film.

16. A photomask comprising:
a substrate; and
a mask film on a surface of the substrate, the mask film including a first mask pattern in a first region of the substrate and a second mask pattern in a second region of the substrate, wherein
a coverage ratio of the first mask pattern is different from a coverage ratio of the second mask pattern, and
a light transmittance rate of light through the substrate in the first region and the first mask pattern is different from a light transmittance rate of the light through the substrate in the second region and the second mask pattern.

17. The photomask according to claim 16, wherein
the coverage ratio of the first mask pattern is less than the coverage ratio of the second mask pattern, and
the light transmittance rate of the light through the substrate in the first region and the first mask pattern is less than the light transmittance rate of the light through the substrate in the second region and the second mask pattern.

18. The photomask according to claim 16, wherein the mask film includes a halftone film.

19. The photomask according to claim 18, wherein the mask film further includes a phase shifter film.

20. The photomask according to claim 16, wherein the substrate includes a shading pattern formed therein.
